(19) United States
(12) Patent Application Publication
(10) Pub. No.: US 2018/0331161 A1
(43) Pub. Date: Nov. 15, 2018

(54) OLED DISPLAY SUBSTRATE AND DISPLAY DEVICE

(71) Applicant: BOE Technology Group Co., Ltd., Beijing (CN)

(72) Inventors: Chinlung Liao, Beijing (CN); Changyen Wu, Beijing (CN)

(21) Appl. No.: 15/839,999

(22) Filed: Dec. 13, 2017

(30) Foreign Application Priority Data
May 12, 2017 (CN) 201710335959.4

(51) Int. Cl. H01L 27/32; H01L 51/52

(52) U.S. Cl. CPC H01L 27/3209; H01L 27/3262; H01L 27/3276; H01L 51/5206; H01L 51/5221; H01L 27/124; H01L 2251/564; H01L 2251/301; H01L 2251/558; H01L 2251/308; H01L 27/3211

(57) ABSTRACT

An OLED display substrate and a display device are provided in the field of display devices. The OLED display substrate includes a plurality of pixel units arranged in an array. Each of the pixel units includes a plurality of sub-pixel units, and each of the sub-pixel units includes two light-emitting units arranged in a laminated mode. At most one of the two light-emitting units in the same sub-pixel unit emits light at one moment. Only one of the two light-emitting units in the same sub-pixel unit is made to emit light at one moment such that the two light-emitting units may be controlled to operate alternately to reduce the time during which each light-emitting unit is continuously on, such that each light-emitting unit has enough time to dissipate heat.

### CROSS-REFERENCE TO RELATED APPLICATION

This application claims priority to Chinese Patent Application No. 201710335959.4, filed with the State Intellectual Property Office on May 12, 2017 and titled “OLED Display Substrate and Display Device,” the entire contents of which are incorporated herein by reference.

### TECHNICAL FIELD

The present disclosure relates to the field of display devices, and more particularly to an OLED display substrate and a display device.

### BACKGROUND

Currently, the common display devices are passive light-emitting display devices and active light-emitting display devices. Compared to passive light-emitting display devices, active light-emitting display devices have advantages of small thickness, low power consumption, and fast response speed, etc., since no backlight is needed. Thus, active light-emitting display devices have greater market competitiveness. Among the active light-emitting display devices, Organic Light Emitting Diode (OLED) display devices are the hot spot of research today for the strong points of wide viewing angle, high contrast and the like.

In an OLED display device, each pixel unit includes three sub-pixel units that emit light of different colors (for example, red, yellow and blue) respectively. The luminous brightness of the three sub-pixel units in the same pixel unit may be controlled such that the pixel unit displays different colors.

### SUMMARY

The present disclosure provides an OLED display substrate and a display device. The technical solutions are as follows:

In an aspect, there is provided an OLED display substrate in the present disclosure. The OLED display substrate comprises a plurality of pixel units arranged in an array. Each of the pixel units includes a plurality of sub-pixel units. Each of the sub-pixel units includes two light-emitting units arranged in a laminated mode and at most one of the two light-emitting units in the same sub-pixel unit emits light at one moment.

In some embodiments, the two light-emitting units in any of the sub-pixel units are configured to emit light of different colors.

In some embodiments, any of the pixel units includes at least two light-emitting units configured to emit blue light.

In some embodiments, two of the at least two light-emitting units configured to emit blue light in any of the pixel units belong to the same sub-pixel unit.

In some embodiments, the two light-emitting units include a first light-emitting unit and a second light-emitting unit. The first light-emitting unit includes a first anode, a first light-emitting layer and a first cathode, and the second light-emitting unit includes a second anode, a second light-emitting layer and a second cathode. The first cathode and the second anode are formed by laminating two conductive layers of different materials, or the first cathode and the second anode are a common electrode.

In some embodiments, in any of the sub-pixel units, the second anode and the first cathode are connected to the same thin film transistor, and the first anode and the second cathode are connected to the same signal line.

In some embodiments, the signal line is configured to input an alternate current signal with a frequency no less than 30 Hz.

In some embodiments, the second anode is made of Ag and the first cathode is made of Au.

In some embodiments, the thickness of the second anode is 2˜5 nm.

In some embodiments, the thickness of the first cathode is 5˜10 nm.

In some embodiments, the common electrode is made of Ca-IZO.

In some embodiments, the thickness of the common electrode is 80˜100 nm.

In some embodiments, each of the pixel units includes three sub-pixel units.

In another aspect, there is further provided an OLED display device in the present disclosure. The OLED display device includes the OLED display substrate described above.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a structural schematic view of an OLED display substrate provided in an embodiment of the present disclosure;

FIG. 2 is a cross sectional view of part A-A in FIG. 1;

FIG. 3 is a top view of a pixel unit provided in an embodiment of the present disclosure;

FIG. 4 is a top view of another pixel unit provided in an embodiment of the present disclosure;

FIG. 5 is a top view of yet another pixel unit provided in an embodiment of the present disclosure;

FIG. 6 is a top view of yet another pixel unit provided in an embodiment of the present disclosure;

FIG. 7 is a structural schematic view of a sub-pixel unit provided in an embodiment of the present disclosure;

FIG. 8 is a structural schematic view of another sub-pixel unit provided in an embodiment of the present disclosure.

### DETAILED DESCRIPTION

Embodiments of the present disclosure will be described in further detail with reference to the enclosed drawings, to clearly present the objects, technique solutions, and advantages of the present disclosure.

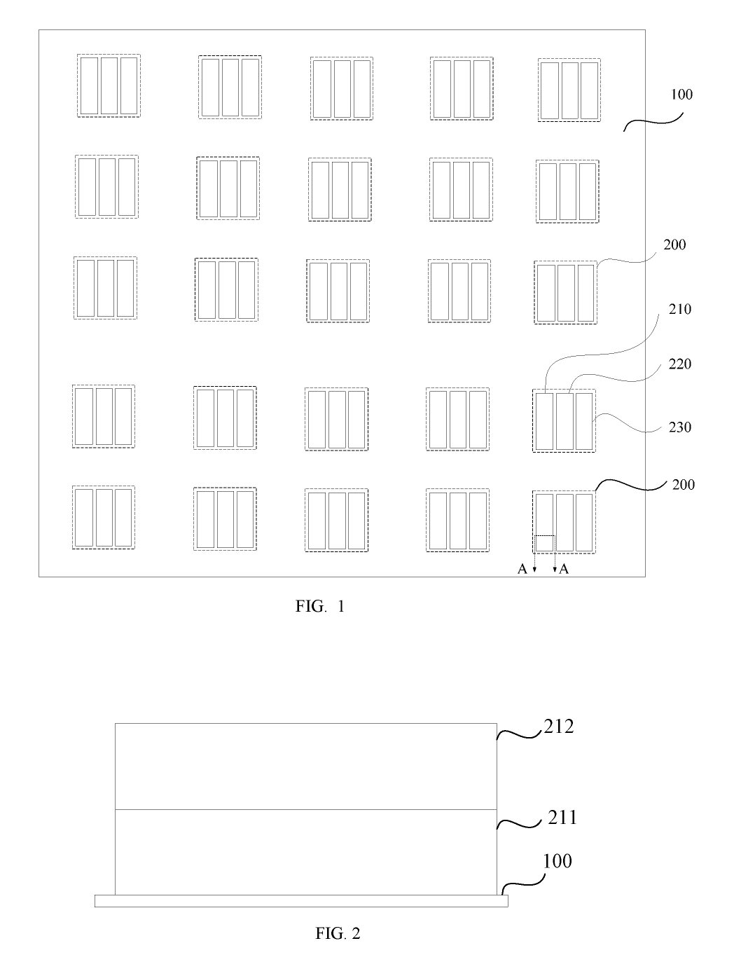

FIG. 1 is a structural schematic view of an OLED display substrate provided in an embodiment of the present disclosure. As shown in FIG. 1, the OLED display substrate includes a plurality of pixel units 200. Each pixel unit 200 includes three sub-pixel units (for example, a first sub-pixel unit 210, a second sub-pixel unit 220 and a third sub-pixel unit 230 shown in FIG. 1). The structure shown in FIG. 1 is exemplified with each pixel unit 200 including three sub-pixel units. In other embodiments, each pixel unit may include four or more sub-pixel units.

FIG. 2 is a cross sectional view of part A-A in FIG. 1. As shown in FIG. 2, each sub-pixel unit includes two light-emitting units arranged in a laminated mode (for example, a first light-emitting unit 211 and a second light-emitting unit 212 shown in FIG. 2). At most one of the two light-emitting units in the same sub-pixel unit emits light at one moment. For example, when the sub-pixel unit operates, one of the two light-emitting units may be controlled to emit light and the two light-emitting units may be used alternately such that each light-emitting unit has enough time to dissipate heat. Thus, the light-emitting units may be effectively protected. When the sub-pixel unit does not operate, both of the two light-emitting units are controlled not to emit light.

In the embodiments of the present disclosure, each sub-pixel unit is provided with two light-emitting units. The problem of short service life can be solved by providing two light-emitting units. When more light emitting units are provided, the thickness of the light-emitting units will be big, resulting in an excessive overall thickness of the OLED display device.

The light-emitting units (including the first light-emitting unit 211 and the second light-emitting unit 212 of the first sub-pixel unit 210, the first light-emitting unit 211 and the second light-emitting unit 212 of the second sub-pixel unit 220, and the first light-emitting unit 211 and the second light-emitting unit 212 of the third sub-pixel unit 230) are all arranged on a substrate 100 and two light-emitting units of the same sub-pixel unit are laminated in a direction perpendicular to the substrate 100.

The substrate 100 may be a basal substrate (may be made of glass, polymer, metal foil, etc.) or an array substrate including a basal substrate and a plurality of thin film transistor (TFT) disposed on the basal substrate in an array. Each sub-pixel unit includes one TFT to control the light-emitting units in the sub-pixel unit to emit light.

In the embodiments of the present disclosure, each pixel unit in the OLED display substrate includes a plurality of sub-pixel units and each sub-pixel unit includes two light-emitting unis arranged in a laminated mode. Only one of the two light-emitting units in the same sub-pixel unit is made to emit light at one moment such that the other one is in a light non-emitting state when one light-emitting unit is in a light emitting state. Therefore, the two light-emitting units may be controlled to operate alternately to reduce the time during which each light-emitting unit is continuously on, such that each light-emitting unit has enough time to dissipate heat. Thus, the light-emitting units may be effectively protected and the ageing of the components may be delayed, thereby lengthening the service life of the display device.

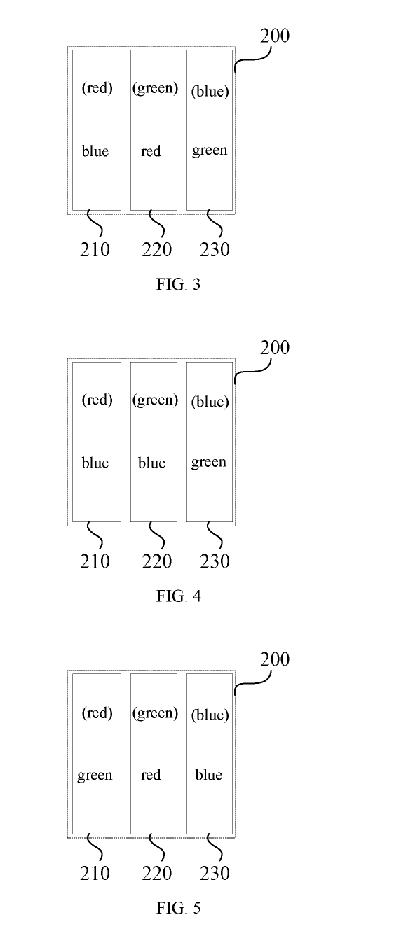

In one implementation of the present disclosure, the two light-emitting units in any sub-pixel unit are configured to emit light of different colors. The implementation will be illustrated in detail with reference to FIG. 3.

FIG. 3 is a top view of a pixel unit provided in an embodiment of the present disclosure. The parenthesized characters refer to the colors of the light emitted by the first light-emitting units in the bottom layer. The unparenthesized characters refer to the colors of the light emitted by the second light-emitting units in the surface layer. As shown in FIG. 3, the first light-emitting unit of the first sub-pixel unit 210, the first light-emitting unit of the second sub-pixel unit 220 and the first light-emitting unit of the third sub-pixel unit 230 emit red light, green light and blue light respectively. The second light-emitting unit of the first sub-pixel unit 210, the second light-emitting unit of the second sub-pixel unit 220 and the second light-emitting unit of the third sub-pixel unit 230 emit blue light, red light and green light respectively. When the light-emitting units in the pixel unit are controlled to operate, the first light-emitting unit of the first sub-pixel unit 210, the first light-emitting unit of the second sub-pixel unit 220 and the first light-emitting unit of the third sub-pixel unit 230 may operate simultaneously, and the second light-emitting unit of the first sub-pixel unit 210, the second light-emitting unit of the second sub-pixel unit 220 and the second light-emitting unit of the third sub-pixel unit 230 may operate simultaneously. Thus, the light-emitting demand of the pixel unit may be guaranteed. Here, the first light-emitting units in the bottom layer are the ones close to the substrate.

It should be noted that in other embodiments, the up-down position of the light-emitting units in one, two or all of the three sub-pixel units may be exchanged. For example, in any sub-pixel unit, the first light-emitting unit may be arranged on the second light-emitting unit.

FIG. 4 is a top view of another pixel unit provided in an embodiment of the present disclosure. As shown in FIG. 4, the first light-emitting unit 211 of the first sub-pixel unit 210 emits red light and the second light-emitting unit 212 thereof emits blue light. The first light-emitting unit 211 of the second sub-pixel unit 220 emits green light and the second light-emitting unit 212 thereof emits blue light. The first light-emitting unit 211 of the third sub-pixel unit 230 emits blue light and the second light-emitting unit 212 thereof emits green light. Compared to the pixel structure in FIG. 3, in the pixel structure in FIG. 4, the light emitted by the two light-emitting units in the same layer (for example, the three first light-emitting units disposed in the same layer) may be of the same color.

In some embodiments, any pixel unit 200 includes at least two light-emitting units configured to emit blue light. The pixel unit 200 shown in FIG. 3 includes two light-emitting units configured to emit blue light, and the pixel unit 200 shown in FIG. 4 includes three light-emitting units configured to emit blue light. The OLED adopts a semiconductor material to emit light and the semiconductor material generating blue light has the shortest service life (for example, about 1000 hours). Therefore, at least two (in particular three) light-emitting units configured to emit blue light are provided in one pixel unit 200. The blue light is generated by the at least two light-emitting units configured to emit blue light, such that the light-emitting units emitting blue light may be controlled to operate alternately to reduce the time during which each light-emitting unit emitting blue light is continuously on, so as to lengthen the service life of the light-emitting units emitting blue light. Alternatively, the at least two light-emitting units emitting blue light may be controlled to be on simultaneously to provide blue light such that the current in each light-emitting unit emitting blue light may be reduced when the brightness of the blue light meets the requirement. Thus, the service life of the light-emitting units emitting blue light may also be lengthened.

In one implementation, in any pixel unit, two of the at least two light-emitting units configured to emit blue light belong to the same sub-pixel unit. As shown in FIG. 5, in the same pixel unit, both of the two light-emitting units in the third sub-pixel unit 230 emit blue light. In the embodiments of the present disclosure, any pixel unit includes two light-emitting units configured to emit blue light that belong to the same sub-pixel unit. Light-emitting units emitting light of different colors have different light-emitting efficiency. Therefore, when a plurality of light-emitting units emitting light of different colors are driven to emit light, the drive voltage for each light-emitting unit may vary. The light-emitting units emitting blue light have a relatively low light-emitting efficiency and the drive voltage for the light-emitting units emitting blue light is usually higher than the drive voltage for the light-emitting units emitting light of other colors. Therefore, the two light-emitting units in a sub-pixel unit may be provided as the light-emitting units emitting blue light such that a relatively low drive voltage may be adopted so as to reduce the power consumption. Meanwhile, the light-emitting layer of the light-emitting units that emit green light and red light may be made of a phosphorescent organic light emitting material with a relatively high light emitting efficiency. While the light-emitting layer of the light-emitting units that emit blue light is made of a fluorescent light emitting material with a relatively low light emitting efficiency. Therefore, the light-emitting units that emit green light and red light are disposed in the same one sub-pixel unit and the light-emitting units that emit blue light are disposed in the same sub-pixel unit, such that when one-path alternate current signal is used to drive the same sub-pixel unit, the brightness of the two light-emitting units in the same one sub-pixel unit may be ensured to be almost the same and meanwhile the brightness difference of the light emitted by the two light-emitting units may be prevented from being too big. Thus, the display effect of the display panel may be improved.

The sub-pixel unit including two light-emitting units configured to emit blue light may be any sub-pixel unit in the pixel unit. For example, the two light-emitting units in the first sub-pixel unit 210 may emit blue light, or the two light-emitting units in the second sub-pixel unit 220 may emit blue light, or the two light-emitting units in the third sub-pixel unit 230 may emit blue light.

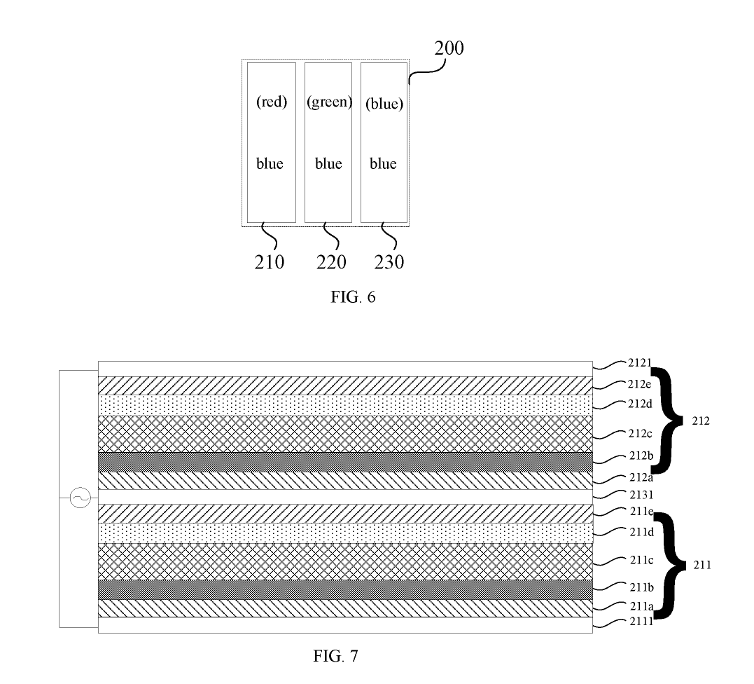

In another implementation of the present disclosure, in the same pixel unit, each sub-pixel unit includes at least one light-emitting unit configured to emit blue light. That is, each sub-pixel unit includes one or two light-emitting units configured to emit blue light. As shown in FIG. 6, in the pixel unit, the first light-emitting unit 211 of the first sub-pixel unit 210 emits red light and the second light-emitting unit 212 thereof emits blue light. The first light-emitting unit 211 of the second sub-pixel unit 220 emits green light and the second light-emitting unit 212 thereof emits blue light. The first light-emitting unit 211 of the third sub-pixel unit 230 emits blue light and the second light-emitting unit 212 thereof also emits blue light. By providing more light-emitting units configured to emit blue light, the total service life of the light-emitting units configured to emit blue light may be lengthened so as to lengthen the service life of the OLED display panel.

FIG. 7 is a structural schematic view of a sub-pixel unit provided in an embodiment of the present disclosure. In the sub-pixel unit shown in FIG. 7, the first light-emitting unit 211 may include a first anode 2111 and a first light-emitting layer 211c. The second light-emitting unit 212 may include a second light-emitting layer 212c and a second cathode 2121. A common electrode 2131 is disposed between the first light-emitting layer 211c and the second light-emitting layer 212c. The common electrode 2131 is used as the first cathode of the first light-emitting unit 211 and the second anode of the second light-emitting unit 212 at the same time to reduce the layer number of the sub-pixel unit and the overall thickness of the OLED display substrate.

In some embodiments, the first light-emitting unit 211 and the second light-emitting unit 212 may emit light of the same color or different colors. For example, the first light-emitting unit 211 and the second light-emitting unit 212 may be enabled to emit light of the same color or different colors based on the needs of different display devices.

In some embodiments, as shown in FIG. 7, the first light-emitting unit 211 may further include a hole injection layer 211a, a hole transport layer 211b, an electron transport layer 211d and an electron injection layer 211e sequentially arranded in a laminated mode. Here, the first light-emitting layer 211c is sandwiched between the hole transport layer 211b and the electron transport layer 211d. The second light-emitting unit 212 may includes a hole injection layer 212a, a hole transport layer 212b, an electron transport layer 212d and an electron injection layer 212e sequentially arranded in a laminated mode. Here, the second light-emitting layer 212c is sandwiched between the hole transport layer 212b and the electron transport layer 212d, and the electron injection layer 211e of the first light-emitting unit 211 and the hole injection layer 212a of the second light-emitting unit 212 respectively contact the common electrode 2131. That is, the first light-emitting unit 211 may further include a hole injection layer 211a, a hole transport layer 211b, an electron transport layer 211d and an electron injection layer 211e. the hole injection layer 211a, the hole transport layer 211b, the first light-emitting layer 211c, the electron transport layer 211d and the electron injection layer 211e are disposed on the first anode 2111 sequentially from bottom to top in a laminated mode. The second light-emitting unit 212 may further include a hole injection layer 212a, a hole transport layer 212b, an electron transport layer 212d and an electron injection layer 212e. The hole injection layer 212a, the hole transport layer 212b, the second light-emitting layer, the electron transport layer 212d and the electron injection layer 212e are disposed on common electrode 2131 sequentially from bottom to top in a laminated mode. The electron injection layer 211e of the first light-emitting unit 211 contacts the common electrode 2131, and the electron injection layer 212e of the second light-emitting unit 212 contacts the second cathode 2121.

In some embodiments, the material of the first light-emitting layer 211c of the first light-emitting unit 211 may be the same as or different from the material of the second light-emitting layer 212c of the second light-emitting unit 212. For example, the material of the first light-emitting layer 211c or the material of the second light-emitting layer 212c may be any of the following materials: Alq3, Almq3 and TBADN.

In some embodiments, the thickness of the first light-emitting layer 211c may be 1000-1500 Å, and the thickness of the second light-emitting layer 212c may be 1000-1500 Å.

The material of the hole injection layer 211a and the hole injection layer 212a may be either of the following materials: m-MTDATA and 2-TNATA. The material of the hole transport layer 211b and the hole transport layer 212b may be any of the following materials: PVK, Spiro-TPD and Spiro-NPB. The material of the electron transport layer 211d and the electron transport layer 212d may be either of the following materials: Alq3 and Almq3. The material of the electron injection layer 211e and the electron injection layer 212e may be either of the following materials: LiF and MgF2.

When the first light-emitting unit 211 is manufactured, all of the hole injection layer 211a, the hole transport layer 211b, the first light-emitting layer 211c, the electron transport layer 211d and the electron injection layer 211e may be formed layer by layer by way of evaporation. The first anode 2111 may be provided with a mask and be formed on the substrate by way of sputtering or evaporation. For example, the first anode 2111 may be formed on the basal substrate by way of sputtering or evaporation. Then, the hole injection layer 211a, the hole transport layer 211b, the first light-emitting layer 211c, the electron transport layer 211d and the electron injection layer 211e may be sequentially formed on the first anode 211 by way of evaporation and patterning, or printing or the like. The common electrode 2131 may be formed on the electron injection layer 211e by way of sputtering or evaporation. The second light-emitting unit 212 may be manufactured in the same way of manufacturing the first light-emitting unit 211. Various layer structures of the second light-emitting unit 212 are formed sequentially on the common electrode 2131 to complete the manufacture of the sub-pixel unit.

In some embodiments, when one side of the second cathode 2121 of the sub-pixel unit is a light emergent side, the common electrode 2131 and the second cathode 2121 are transparent electrodes and the first anode 2111 may be a non-transparent electrode or a transparent electrode. When one side of the first anode 2111 of the sub-pixel unit is a light emergent side, the common electrode 2131 and the first anode 2111 are transparent electrodes and the second cathode 2121 may be a non-transparent electrode or a transparent electrode.

For example, the transparent electrode may be a metal, an alloy of several metals, or an oxide with good conductivity, such as Al, Mg, Ca, Yb, Mg:Ag, Yb:Ag, ITO, IZO and the like. The non-transparent electrode may be a metal, an alloy of several metals, or an oxide with good conductivity, such as Ag, Au, Pd, Pt, Ag:Au, Ag:Pd, Ag:Pt, Al:Au, Al:Pd, Al:Pt, Ag:Au, Au/Ag, Pd/Ag, Pt/Ag and the like. Here, Ag:Au refers to an alloy of Ag and Au. Au/Ag refers to an Au layer and an Ag layer which are laminated. The method for expressing the alloy and laminating structure of other materials is the same as the one here.

In the embodiments of the present disclosure, the first anode 2111 is a non-transparent electrode and the thickness of the first anode 2111 may be 50˜100 nm. The second cathode 2121 is a transparent electrode. When the second cathode 2121 is made of a metal material, the thickness of the second cathode 2121 may be 10˜20 nm, such that the second cathode 2121 has sufficient transmissivity. When the second cathode 2121 is made of a transparent material, such as ITO and IZO, the thickness of the second cathode 2121 may be 80˜100 nm.

In the embodiments of the present disclosure, the common electrode 2131 may be made of Ca-IZO. Ca-IZO has relatively high transmissivity, which may reduce the absorption of light. In some embodiments, the thickness of the common electrode is 80˜100 nm.

During implementation, in any sub-pixel unit, the common electrode 2131 is connected to a thin film transistor such that the sub-pixel unit may be controlled to operate or not. The first anode 2111 and the second cathode 2121 are connected to the same signal line such that the sub-pixel unit may be controlled to emit light through the thin film transistor and the signal line.

Here, the signal line is configured to input an alternate current signal with a frequency no less than 30 Hz. It may realize that the two light-emitting units in the same sub-pixel unit emit light alternately by inputting the alternate current signal. Meanwhile, the frequency of the alternate current signal is set to be no less than 30 Hz such that users may not observe the flicker of the light-emitting units with eyes. For example, the frequency of the alternate current signal may be 50-60 Hz.

When the electric potential of the first anode 2111 and the second cathode 2121 is higher than that of the common electrode 2131, current is injected from the first anode 2111 and flows out from the common electrode 2131 and the first light-emitting unit 211 emits light. When the electric potential of the first anode 2111 and the second cathode 2121 is lower than that of the common electrode 2131, current is injected from the common electrode 2131 and flows out from the second cathode 2121 and the second light-emitting unit 212 emits light. For this, one-path alternate current signal may be input to the first anode 2111 and the second cathode 2121 such that the two light-emitting units may work alternately. In addition, the alternate current signal may be set to be with a relatively high frequency such that users may not observe the flicker of the light-emitting units with eyes. Since the frequency is relatively high, even though the first light-emitting unit and the second light-emitting do not actually emit light at the same time, users may observe that the two light-emitting units emit light at the same time. Therefore, different colors are displayed.

It should be noted that in the embodiments of the present disclosure, the alternate current signal is a signal that provides a positive voltage and a negative voltage alternately. In addition, the alternate frequency and amplitude between the positive voltage and the negative voltage, as well as the duration of the positive voltage and the negative voltage may be set based on actual needs. In the embodiments of the present disclosure, both the positive voltage and the negative voltage may be equal to 0. By adopting the alternate current signal to drive the light-emitting units to emit light, the positive voltage and the negative voltage may be applied to the same light-emitting unit alternately, such that the accumulated charge in the light-emitting layer of the light-emitting units may be reduced, thereby lengthening the service life of the light-emitting units.

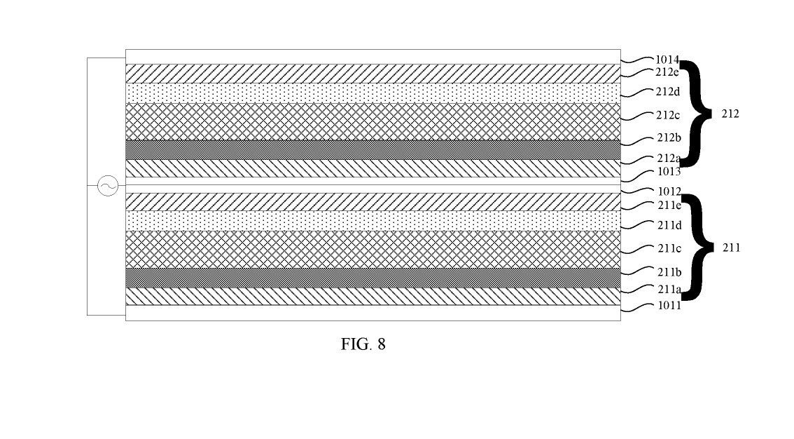

FIG. 8 is a structural schematic view of another sub-pixel unit provided in an embodiment of the present disclosure. The structure of the sub-pixel unit may be the same as that shown in FIG. 7 and the difference therebetween lies in the following: in the sub-pixel unit shown in FIG. 8, the first light-emitting unit 211 may include a first anode 1101, a first light-emitting layer 211c and a first cathode 1012 and the second light-emitting unit 212 may include a second anode 1013, a second light-emitting layer 212c and a second cathode 1014 sequentially laminated on the first anode 1012, and the second anode 1013 is disposed on the first cathode 1012.

During implementation, in any of the sub-pixel units, the second anode 1013 and the first cathode 1012 are connected to the same thin film transistor, and the first anode 1101 and the second cathode 1014 are connected to the same signal line, such that the sub-pixel unit may be controlled to emit light through the thin film transistor and the signal line.

The signal line is configured to input an alternate current signal with a frequency no less than 30 Hz. By inputting the alternate current signal, it may realize that the two light-emitting units in the same sub-pixel unit emit light alternately. Meanwhile, the frequency of the alternate current signal is set to be no less than 30 Hz, such that users may not observe the flicker of the light-emitting units with eyes. For example, the frequency of the alternate current signal may be 50-60 Hz.

The second anode 1013 is made of Ag and the first cathode 1012 is made of Au. The relatively thin Au layer may be used as a wetting layer. Therefore, it may be guaranteed that the second anode may be formed by a film made of Ag on the Au layer and with a relatively low thickness. In this case, the thickness of the second anode 1013 may be 2˜5 nm and the thickness of the first cathode 1012 may be 5˜10 nm.

Further, the sum of the thickness of the first anode 1012 and the thickness of the second anode 1013 does not exceed 20 nm, such that first anode 1012 and the second anode 1013 have sufficient transmissivity to reduce the absorption of light.

In some embodiments, the first sub-pixel unit 210, the second sub-pixel unit 220 and the third sub-pixel unit 230 may be rectangular, regular hexagonal, fan-shaped or the like. For different display devices, the sub-pixel unit may be set to be in different shapes to meet different design requirements.

During implementation, all of the first sub-pixel unit 210, the second sub-pixel unit 220 and the third sub-pixel unit 230 may be provided with the sub-pixel structure shown in FIG. 7 or FIG. 8.

The embodiments of the present disclosure further provide a display device. The display device includes the OLED display substrate shown in FIG. 1. During implementation, the OLED display device provided in the embodiments of the present disclosure may be a mobile phone, a tablet computer, a TV, a display, a laptop computer, a digital photo frame, a navigator or any other product or part with display function.

In the embodiments of the present disclosure, each pixel unit in the OLED display substrate includes a plurality of sub-pixel units and each sub-pixel unit includes two light-emitting unis arranged in a laminated mode. Only one of the two light-emitting units in the same sub-pixel unit is made to emit light at one moment such that the other one is in a light non-emitting state when one light-emitting unit is in a light emitting state. Therefore, the two light-emitting units may be controlled to operate alternately to reduce the time during which each light-emitting unit is continuously on, such that each light-emitting unit has enough time to dissipate heat. Thus, the light-emitting units may be effectively protected and the ageing of the components may be delayed, thereby lengthening the service life of the display device.

The foregoing are only some embodiments of the present disclosure, and are not intended to limit the present disclosure. Within the spirit and principles of the disclosure, any modifications, equivalent substitutions, improvements, etc., are within the scope of protection of the present disclosure.

What is claimed is:

1. An OLED display substrate, comprising a plurality of pixel units arranged in an array, wherein each of the pixel units includes a plurality of sub-pixel units, each of the sub-pixel units includes two light-emitting units arranged in a laminated mode and at most one of the two light-emitting units in the same sub-pixel unit emits light at one moment.

2. The OLED display substrate of claim 1, wherein the two light-emitting units in any of the sub-pixel units are configured to emit light of different colors.

3. The OLED display substrate of claim 1, wherein any of the pixel units includes at least two light-emitting units configured to emit blue light.

4. The OLED display substrate of claim 3, wherein two of the at least two light-emitting units configured to emit blue light in any of the pixel units belong to the same sub-pixel unit.

5. The OLED display substrate of claim 1, wherein the two light-emitting units include a first light-emitting unit and a second light-emitting unit, the first light-emitting unit includes a first anode, a first light-emitting layer and a first cathode, the second light-emitting unit includes a second anode, a second light-emitting layer and a second cathode, the first cathode and the second anode are formed by laminating two conductive layers of different materials, or the first cathode and the second anode are a common electrode.

6. The OLED display substrate of claim 5, wherein in any of the sub-pixel units, the second anode and the first cathode are connected to a same thin film transistor, and the first anode and the second cathode are connected to a same signal line.

7. The OLED display substrate of claim 6, wherein the signal line is configured to input an alternate current signal with a frequency no less than 30 Hz.

8. The OLED display substrate of claim 5, wherein the second anode is made of Ag and the first cathode is made of Au.

9. The OLED display substrate of claim 8, wherein a thickness of the second anode is 2˜5 nm.

10. The OLED display substrate of claim 9, wherein a thickness of the first cathode is 5˜10 nm.

11. The OLED display substrate of claim 5, wherein the common electrode is made of Ca-IZO.

12. The OLED display substrate of claim 11, wherein a thickness of the common electrode is 80˜100 nm.

13. The OLED display substrate of claim 1, wherein each of the pixel units includes three sub-pixel units.

14. An OLED display device, comprising an OLED display substrate, wherein the OLED display substrate includes a plurality of pixel units arranged in an array, each of the pixel units includes a plurality of sub-pixel units, each of the sub-pixel units includes two light-emitting units arranged in a laminated mode and at most one of the two light-emitting units in the same sub-pixel unit emits light at one moment.

15. The OLED display device of claim 14, wherein the two light-emitting units in any of the sub-pixel units are configured to emit light of different colors.

16. The OLED display device of claim 14, wherein any of the pixel units includes at least two light-emitting units configured to emit blue light.

17. The OLED display device of claim 16, wherein two of the at least two light-emitting units configured to emit blue light in any of the pixel units belong to the same sub-pixel unit.

18. The OLED display device of claim 14, wherein the two light-emitting units include a first light-emitting unit and a second light-emitting unit, the first light-emitting unit includes a first anode, a first light-emitting layer and a first cathode, the second light-emitting unit includes a second anode, a second light-emitting layer and a second cathode, the first cathode and the second anode are formed by laminating two conductive layers of different materials, or the first cathode and the second anode are a common electrode.

19. The OLED display device of claim 18, wherein in any of the sub-pixel units, the second anode and the first cathode are connected to a same thin film transistor, and the first anode and the second cathode are connected to a same signal line.

20. The OLED display device of claim 19, wherein the signal line is configured to input an alternate current signal with a frequency no less than 30 Hz.
